(19) United States
(12) Patent Application Publication
(10) Pub. No.: US 2026/0164965 A1
(43) Pub. Date: Jun. 11, 2026

(54) Display Apparatus

(71) Applicant: LG Display Co., Ltd., Seoul (KR)

(72) Inventors: Junyoung Lee, Paju-si (KR); Hyungrae Kim, Paju-si (KR); Sanggoo Kwon, Paju-si (KR)

(21) Appl. No.: 19/185,890

(22) Filed: Apr. 22, 2025

(30) Foreign Application Priority Data
Dec. 5, 2024 (KR) 10-2024-0179346

(51) Int. Cl. H10K 59/131; G09G 3/3233

(52) U.S. Cl. CPC H10K 59/131; G09G 3/3233; G09G 2300/0413; G09G 2300/0842

(57) ABSTRACT

A display apparatus includes a display panel including a pad area where a first driving voltage line and a second driving voltage line that is spaced apart from the first driving voltage line are arranged, and a first circuit substrate connected to the pad area, wherein an end of the first driving voltage line is aligned with an end of the display panel, and an end of the second driving voltage line is spaced apart from the end of the display panel.

### CROSS REFERENCE TO RELATED APPLICATION

The present application claims priority to Republic of Korea Patent Application No. 10-2024-0179346, filed on Dec. 5, 2024, which is hereby incorporated by reference in its entirety.

### BACKGROUND

### Field of Technology

This specification relates to a display apparatus.

### Description of the Related Art

With the advancement of the information society, there is an increasing demand for display devices that can show images, and various types of display devices such as liquid crystal display (LCD) devices and organic light emitting diode (OLED) displays are being utilized.

The display panel of the display device may include a plurality of organic light-emitting elements, and each organic light-emitting element may include an anode electrode, an organic layer, and a cathode electrode.

### SUMMARY

It is an object of this specification to provide a display apparatus capable of improving (e.g., reducing) a short circuit between a driving voltage line and an adjacent line by additionally disposing dummy lines on both sides of the driving voltage line.

It is another object of this specification to provide a display apparatus capable of enhancing longevity and reducing power consumption by improving a short circuit between the driving voltage line and an adjacent line.

The objects of this specification are not limited to the foregoing, and other objects may be inferred from the following embodiments.

A display apparatus according to an embodiment of this specification includes a display panel including a pad area where a first driving voltage line and a second driving voltage line spaced apart from the first driving voltage line are arranged, and a first circuit substrate connected to the pad area, wherein an end of the first driving voltage line is aligned with an end of the display panel, and an end of the second driving voltage line is spaced apart from the end of the display panel.

A display apparatus according to an embodiment of this specification includes a display panel including a pad area where a first driving voltage line and a second driving voltage line spaced apart from the first driving voltage line are arranged, and a first circuit substrate connected to the pad area, wherein an end of the first driving voltage line and an end of the second driving voltage line are each aligned with an end of the display panel, and dummy lines are further arranged on both sides of the first driving voltage line and on both sides of the second driving voltage line.

The specific details of other embodiments are included in the detailed description and drawings.

### BRIEF DESCRIPTION OF THE DRAWINGS

FIG. 1 is a schematic view of a display apparatus according to an embodiment;

FIG. 2 is a plan view illustrating a rear surface of a display apparatus according to an embodiment;

FIG. 3 is a diagram of a circuit constituting a pixel in a display apparatus according to an embodiment;

FIG. 4 is an enlarged plan view of a Q1 area of FIG. 2 according to an embodiment;

FIG. 5 is a cross-sectional view taken along line I-I′ of FIG. 4 according to an embodiment;

FIG. 6 is a plan view illustrating a process step in a method of manufacturing a display panel according to an embodiment;

FIG. 7 is a plan view of a display apparatus according to another embodiment;

FIG. 8 is a cross-sectional view taken along line II-II′ of FIG. 7 according to an embodiment; and

FIG. 9 is a plan view of a display apparatus according to another embodiment.

### DETAILED DESCRIPTION

Hereinafter, embodiments are described with reference to accompanying drawings. In the specification, when a component (or area, layer, part, etc.) is mentioned as being “on top of,” “connected to,” or “coupled to” another component, it means that it may be directly connected/coupled to the other component, or a third component may be placed between them.

The same reference numerals refer to the same components. In addition, in the drawings, the thickness, proportions, and dimensions of the components are exaggerated for effective description of the technical content. The expression “and/or” is taken to include one or more combinations that can be defined by associated components.

The terms “first,” “second,” etc. are used to describe various components, but the components should not be limited by these terms. The terms are used only for distinguishing one component from another component. For example, a first component may be referred to as a second component and, similarly, the second component may be referred to as the first component, without departing from the scope of the embodiments. The singular forms are intended to include the plural forms as well unless the context clearly indicates otherwise.

The terms such as “below,” “lower,” “above,” “upper,” etc. are used to describe the relationship of components depicted in the drawings. The terms are relative concepts and are described based on the direction indicated on the drawing.

It will be further understood that the terms “comprises,” “has,” and the like are intended to specify the presence of stated features, numbers, steps, operations, components, parts, or a combination thereof but are not intended to preclude the presence or possibility of one or more other features, numbers, steps, operations, components, parts, or combinations thereof.

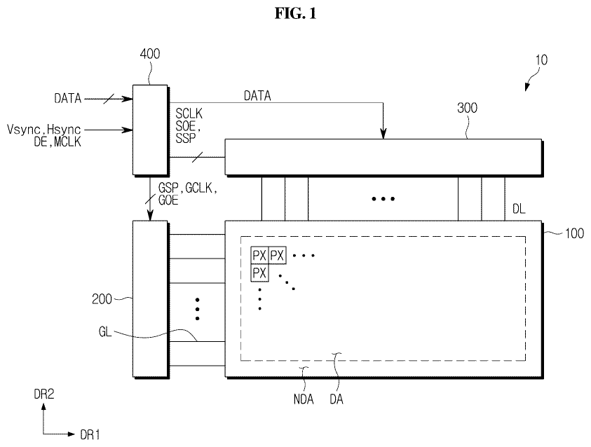

FIG. 1 is a schematic view of a display apparatus according to an embodiment;

Referring to FIG. 1, a display apparatus 10 according to an embodiment may include a display panel 100 comprising a plurality of gate lines GL and data lines DL that are connected to a plurality of pixels PX arranged in the display panel 100, a gate driving circuit 200 that provides signals to the plurality of gate lines GL, a first circuit board 300 that supplies data voltages through the plurality of data lines DL, and a timing controller 400 that controls the gate driving circuit 200 and the first circuit board 300.

The display panel 100 displays an image based on the scan signals transmitted from the gate driving circuit 200 through the plurality of gate lines GL and the data voltages transmitted from the first circuit board 300 through the plurality of data lines DL.

In the case of a liquid crystal display, the display panel 100 includes a liquid crystal layer formed between two substrates and may operate in any known modes such as a twisted nematic mode (TN), a vertical alignment mode (VA), an in-plane switching mode (IPS), and a fringe field switching mode (FFS). In contrast, in the case of an organic light-emitting display, the display panel 100 may be implemented in a top emission method, a bottom emission method, or a dual emission method.

The display panel 100 may include a plurality of pixels PX, and each pixel PX includes pixels of different colors, such as the white (W) subpixel, the red (R) subpixel, the green (G) subpixel, and the blue (B) subpixel, with each pixel PX defined by a plurality of data lines DL and a plurality of gate lines GL.

A pixel PX may include a thin film transistor (TFT) arranged in an area formed by a data line DL and a gate line GL, a light-emitting element such as a light-emitting diode that emits light based on a data voltage, and a storage capacitor electrically connected to the light-emitting element to maintain voltage.

For example, assuming a display apparatus 10 with a resolution of 2,600 by 3,840 and four pixels PX, the white (W) pixel, the red (R) pixel, the green (G) pixel, and the blue (B) pixel constituting a pixel unit, the display apparatus 10 may be equipped with 2,600 gate lines GL and 3,840 data lines DL each connected to the four subpixels (WRGB), resulting in a total of 3,840 times 4 equals 15,360 data lines DL, with pixels PX arranged in the areas formed by these gate lines GL and data lines DL.

The gate driving circuit 200 is controlled by the timing controller 400, outputting scan signals sequentially to a plurality of gate lines GL arranged in the display panel 100, thereby controlling the driving timing for a plurality of pixels PX.

In a display apparatus 10 with a resolution of 2,600 by 3,840, outputting scan signals sequentially from the first gate line to the 2,600th gate line for 2,600 gate lines GL is referred to as 2,600-phase driving. Alternatively, outputting scan signals sequentially in units of four gate lines GL, such as outputting scan signals sequentially from the first gate line to the fourth gate line and then from the fifth gate line to the eighth gate line, is referred to as 4-phase driving. That is, outputting scan signals sequentially for every N gate lines GL is referred to as N-phase driving.

Here, the gate driving circuit 200 may include one or more gate driving integrated circuits (GDIC), and depending on the driving method, the gate driving circuit 200 may be positioned on only one side of the display panel 100 or on both sides of the display panel 100. Alternatively, the gate driving circuit 200 may be implemented in a gate-in-panel (GIP) form directly formed in the bezel area of the display panel 100.

The first circuit board 300 receives digital image data DATA from the timing controller 400 and converts the received digital image data DATA into analog data voltages. Then, by outputting the data voltages to the respective data lines DL in synchronization with the timing at which scan signals are applied to the gate lines GL, each pixel PX connected to the data lines DL displays a light emission signal corresponding to the brightness of the data voltage.

Similarly, the first circuit board 300 may include one or more source driving integrated circuits (SDICs), which may be connected to the bonding pads of the display panel 100 using a tape-automated bonding (TAB) method or a chip-on-glass (COG) method, or may be directly disposed on the display panel 100.

In some cases, each source driving integrated circuit (SDIC) may be integrated into and disposed within the display panel 100. Additionally, each source driving integrated circuit (SDIC) may be implemented in a chip-on-film (COF) method, in this configuration, each source driving integrated circuit (SDIC) is mounted on a circuit film and electrically connected to the data lines DL of the display panel 100 via the circuit film.

The timing controller 400 supplies various control signals to the gate driving circuit 200 and the first circuit board 300, thereby controlling their operations. That is, the timing controller 400 controls the gate driving circuit 200 to output scan signals according to the timing required for each frame, while also transmitting the externally received digital image data DATA to the first circuit board 300.

In this process, the timing controller 400 receives various timing signals from an external source (e.g., a host system), including a vertical synchronization signal Vsync, a horizontal synchronization signal Hsync, a data enable signal DE, and a main clock MCLK, along with the digital image data DATA. Accordingly, the timing controller 400 generates control signals based on the received timing signals and transmits them to the gate driving circuit 200 and the first circuit board 300.

For example, to control the gate driving circuit 200, the timing controller 400 outputs various gate control signals, such as a gate start pulse GSP, a gate clock GCLK, and a gate output enable signal GOE. Here, the gate start pulse GSP controls the timing at which one or more gate driving integrated circuits (GDICs) included in the gate driving circuit 200 begin operating. Additionally, the gate clock GCLK is a clock signal commonly supplied to one or more (GDICs) and controls the shift timing of the scan signals. Additionally, the gate output enable signal GOE specifies the timing information of one or more gate driving integrated circuits (GDICs).

Furthermore, to control the first circuit board 300, the timing controller 400 outputs various data control signals, including a source start pulse SSP, a source sampling clock SCLK, and a source output enable signal SOE. Here, the source start pulse SSP controls the timing at which one or more source driving integrated circuits (SDICs) included in the first circuit board 300 begin data sampling. The source sampling clock SCLK is a clock signal that controls the timing for data sampling in the source driving integrated circuits (SDICs). The source output enable signal SOE controls the output timing of the first circuit board 300.

The display apparatus 10 may further include a power management integrated circuit (PMIC) that supplies various voltages or currents to components such as the display panel 100, the gate driving circuit 200, and the first circuit board 300, or controls the voltages or currents to be supplied.

Meanwhile, a light-emitting element may be arranged in each pixel PX. For example, an organic light-emitting display apparatus includes a light-emitting element, such as a light-emitting diode, in each pixel PX, and displays an image by controlling the current flowing through the light-emitting element according to the data voltage.

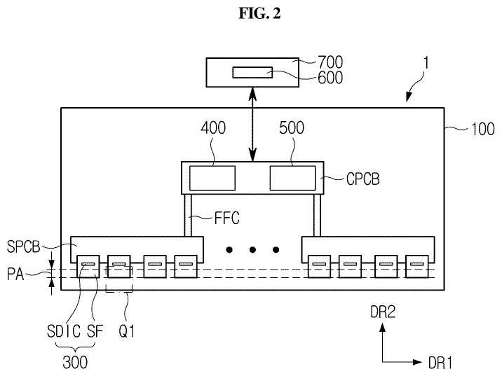

FIG. 2 is a plan view illustrating a rear surface of a display apparatus according to an embodiment;

In the embodiment of FIG. 2, the display apparatus 10 includes a source driving integrated circuit (SDIC) within the first circuit board 300, implemented using the chip-on-film (COF) method, and the gate driving circuit 200 is implemented in a gate-in-panel (GIP) form, among various methods such as tape automated bonding (TAB), chip-on-glass (COG), chip-on-film (COF), and gate-in-panel (GIP).

When the gate driving circuit 200 (FIG. 1) is implemented in a gate-in-panel (GIP) form, a plurality of gate driving integrated circuits (GDICs) included in the gate driving circuit 200 may be directly formed in the bezel area of the display panel 100. In this case, the gate driving integrated circuits (GDICs) can receive various signals necessary for generating the scan signal SCAN, such as clock signals, gate high signals, and gate low signals, through gate driving-related signal lines disposed in the bezel area.

Similarly, one or more source driving integrated circuits SDICs included in the first circuit board 300 may be mounted on a source film SF, with one side of the source film SF being electrically connected to the display panel 100. Additionally, lines for electrically connecting the source driving integrated circuits SDICs and the display panel 100 can be disposed on the top of the source film SF.

This display apparatus 10 may further include at least one source printed circuit board SPCB (or second circuit board) for the circuit connection between a plurality of source driving integrated circuits SDICs and other devices, and a control printed circuit board CPCB (or third circuit board) for mounting control components and various electrical devices.

In this case, the opposite side of the source film SF with the source driving integrated circuit SDIC mounted can be connected to at least one source printed circuit board SPCB. That is, the source film SF with the source driving integrated circuit SDIC mounted may have one side electrically connected to the display panel 100 and the opposite side electrically connected to the source printed circuit board SPCB. For example, a plurality of source films SF may be connected to a single source printed circuit board SPCB, but is not limited to this configuration.

The control printed circuit board CPCB may include a timing controller 400 and a power management circuit (PMIC) 500. The timing controller 400 may control the operation of the first circuit board 300 and the gate driving circuit 200. The power management circuit 500 may supply drive voltages or currents to the display panel 100, the first circuit board 300, and the gate driving circuit 200, and may also control the supplied voltages or currents.

At least one source printed circuit board SPCB and the control printed circuit board CPCB may be electrically connected through at least one connecting member, such as a flexible printed circuit FPC, a flexible flat cable FFC, etc. For example, the source printed circuit board SPCB may be plural, and a plurality of source printed circuit boards SPCBs may be connected to a single control printed circuit board CPCB. In this case, a single source printed circuit board SPCB may be connected to the control printed circuit board CPCB through a plurality of flexible flat cables FFCs.

The display apparatus 10 may further include a set board 700 electrically connected to the control printed circuit board CPCB. In this case, the set board 700 may also be referred to as a power board. The set board 700 may include a main power management circuit M-PMC 600 that manages the overall power of the display apparatus 10. The main power management circuit 600 may interact with the power management circuit 500.

In a display apparatus 10 configured as described above, the drive voltage is generated in the set board 700 and transferred to the power management circuit 500 within the control printed circuit board CPCB. The power management circuit 500 may transfer the drive voltage required for display driving or characteristic value sensing to the source printed circuit board SPCB through a flexible printed circuit FPC or a flexible flat cable FFC. The drive voltage transferred to the source printed circuit board SPCB is supplied to a specific pixel PX within the display panel 100 through the source driving integrated circuit SDIC for emission or sensing.

Each pixel PX arranged in the display panel 100 of the display apparatus 10 may be composed of circuit components, such as an emission element and a driving transistor for driving it.

The types and number of circuit components constituting each pixel PX may vary depending on the provided functionality and design approach.

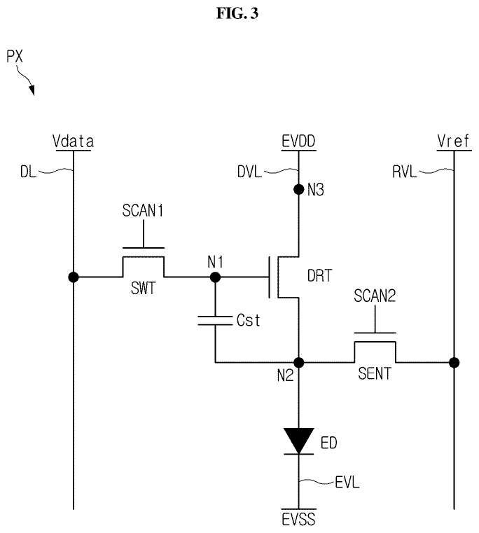

FIG. 3 is a diagram of a circuit constituting a pixel in a display apparatus according to an embodiment;

Referring to FIG. 3, in a display apparatus 10 according to one embodiment, the pixel PX may include one or more transistors and a capacitor, and an organic light-emitting diode may be arranged as the light-emitting element ED.

For example, the pixel PX may include a driving transistor DRT, a switching transistor SWT, a sensing transistor SENT, a storage capacitor Cst, and a light-emitting element ED.

The driving transistor DRT may have a first node N1, a second node N2, and a third node N3. The first node N1 of the driving transistor DRT may be a gate node where a data voltage Vdata is applied from the first circuit board 300 through the data line DL when the switching transistor SWT is turned on. The second node N2 of the driving transistor DRT may be electrically connected to the anode electrode of the light-emitting element ED and may be the source or drain node. The third node N3 of the driving transistor DRT may be electrically connected to the driving voltage line DVL, to which a driving voltage EVDD is applied, and may be the drain or source node.

During the display driving period, the driving voltage EVDD required to display an image may be supplied through the driving voltage line DVL, and for example, the driving voltage EVDD required to display the image may be 27V.

The switching transistor SWT is electrically connected between the first node N1 of the driving transistor DRT and the data line DL, with the gate line GL connected to the gate node, and operates according to the scan signal SCAN supplied through the gate line GL. Additionally, when the switching transistor SWT is turned on, the switching transistor SWT controls the operation of the driving transistor DRT by transmitting the data voltage Vdata, supplied through the data line DL, to the gate node of the driving transistor DRT.

The sensing transistor SENT is electrically connected between the second node N2 of the driving transistor DRT and the reference voltage line RVL, with the gate line GL connected to the gate node, and operates according to the sense signal SENSE supplied through the gate line GL. When the sensing transistor SENT is turned on, the sensing reference voltage Vref, supplied through the reference voltage line RVL, is delivered to the second node N2 of the driving transistor DRT.

That is, by controlling the switching transistor SWT and the sensing transistor SENT, the voltages at the first node N1 and the second node N2 of the driving transistor DRT are controlled, enabling the supply of current to drive the light-emitting element ED.

The gate nodes of the switching transistor SWT and the sensing transistor SENT may be connected to the same gate line GL or to different gate lines GL. In this embodiment, the switching transistor SWT and the sensing transistor SENT are connected to different gate lines GL, which allows independent control of the switching transistor SWT and the sensing transistor SENT via the scan signal SCAN and the sense signal SENSE transmitted through the different gate lines GL.

In contrast, when the switching transistor SWT and the sensing transistor SENT are connected to the same gate line GL, the switching transistor SWT and the sensing transistor SENT may be simultaneously controlled by the scan signal SCAN or the sense signal SENSE transmitted through the same gate line GL, which may increase the aperture ratio of the pixel PX.

Meanwhile, the transistors arranged in the pixel PX may include not only n-type transistors but also p-type transistors, and this example illustrates a configuration using n-type transistors.

The storage capacitor Cst is electrically connected between the first node N1 and the second node N2 of the driving transistor DRT, maintaining the data voltage Vdata for one frame.

Depending on the type of the driving transistor DRT, the storage capacitor Cst may also be connected between the first node N1 and the third node N3 of the driving transistor DRT instead of the second node N2 as shown in FIG. 3. The anode electrode of the light-emitting element ED may be electrically connected to the second node N2 of the driving transistor DRT, and the cathode electrode of the light-emitting element ED may be supplied with a base voltage EVSS.

Here, the base voltage EVSS may be a ground voltage or a voltage higher or lower than the ground voltage. Furthermore, the base voltage EVSS may be variable depending on the driving state, and for example, the base voltage EVSS at the time of display driving and the base voltage EVSS at the time of sensing driving may be set differently.

The structure of the pixel PX described above, as an example, follows a 3 T (transistor) 1 C (capacitor) configuration and serves only as an example, potentially including one or more additional transistors or, in some cases, one or more additional capacitors. Alternatively, multiple pixels PX may have the same structure, or some of the pixels PX may have a different structure.

The display apparatus 10 according to one embodiment may use a current sensing method to measure the current flowing through the voltage charged to the storage capacitor Cst in the characteristic value sensing section of the driving transistor DRT, in order to effectively sense the characteristic value of the driving transistor DRT, such as its threshold voltage or mobility.

That is, by measuring the current flowing through the voltage charged to the storage capacitor Cst in the characteristic value sensing section of the driving transistor DRT, the characteristic value or change in the characteristic value of the driving transistor DRT in the pixel PX can be determined.

Here, the reference voltage line RVL serves not only to transmit the reference voltage Vref but also functions as a sensing line for sensing the characteristic values of the driving transistor DRT within the pixel PX, and thus the reference voltage line RVL may be referred to as a sensing line.

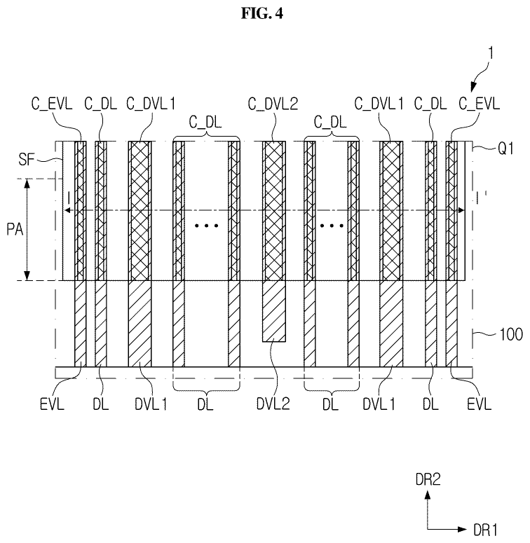

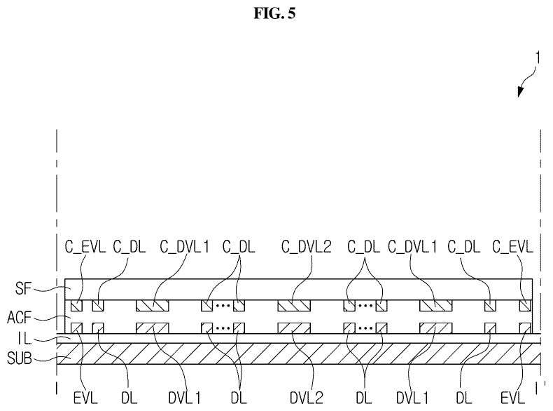

FIG. 4 is an enlarged plan view of a Q1 area of FIG. 2 according to an embodiment. FIG. 5 is a cross-sectional view taken along line I-I′ of FIG. 4 according to an embodiment.

Referring to FIGS. 4 and 5, the display panel 100 of the display apparatus 1 according to one embodiment may include a pad area PA. The pad area PA may be connected to the source film SF of the first circuit substrate.

The display panel 100 may include an end extending along a first direction DR1. From the end of the display panel 100, a plurality of lines may extend in a second direction DR2 in one side. For example, the display panel 100 may include a substrate SUB, an insulating layer IL on the substrate SUB, and a plurality of lines EVL, DL, DVL1, and DVL2 on the insulating layer IL.

The substrate SUB may be a rigid substrate such as glass or quartz, or a flexible substrate including a plastic material. For example, the substrate SUB may be a multi-substrate including a plurality of plastic materials such as polyimide, but the embodiments of this specification are not limited thereto.

The substrate SUB may include a rear side facing the insulating layer IL and a front side facing the opposite of the insulating layer IL. The first circuit substrate may be disposed on the rear side of the substrate SUB. The front side of the substrate SUB may be the light-emitting surface of the display apparatus 1. However, the embodiments of this specification are not limited thereto, and lines may also be arranged on the front side of the substrate SUB, with the front side being the light-emitting surface.

An insulating layer IL may be disposed on the substrate SUB. The insulating layer IL may be formed by alternately stacking at least one layer of silicon nitride (SiNx) and silicon oxide (SiOx), but the embodiments of this specification are not limited to this.

A plurality of lines may be disposed on the insulating layer IL. The plurality of lines may include the driving voltage lines DVL1 and DVL2, the base voltage line EVL, and the data line DL. The driving voltage lines DVL1 and DVL2, base voltage line EVL, and data line DL may be disposed in the pad area PA and may extend toward the edge of the display panel 100.

The base voltage line EVL may be located on opposite sides of the first direction DR1. In some embodiments, a gate control line may further be disposed next to the base voltage line EVL. The end of the base voltage line EVL may be aligned with the end of the display panel 100 (or the end of the substrate SUB).

On one side of the base voltage line EVL in the first direction DR1, the data line DL may be disposed. In FIG. 4, a single data line DL is shown as being arranged in the first direction DR1 of the base voltage line EVL, but the embodiments of this specification are not limited thereto, and a plurality of data lines DL may be arranged in the first direction DR1 of the base voltage line EVL. The ends of the data lines DL may be aligned with the ends of the display panel 100 (or the substrate SUB).

On one side of the data line DL in the first direction DR1, the first driving voltage line DVL1 may be arranged. The first driving voltage line DVL1 and the second driving voltage line DVL2, which will be described later, may extend toward the second direction DR2 and may be electrically connected to each other. That is, the first and second driving voltage lines DVL1 and DVL2 may be electrically connected to the pixels PX. The end of the first driving voltage line DVL1 may be aligned with the end of the display panel 100 (or the substrate SUB).

On one side of the first driving voltage line DVL1 in the first direction DR1, a plurality of data lines DL may be arranged.

On one side of the first direction DR1 of the plurality of data lines DL, the second driving voltage line DVL2 may be arranged. The end of the second driving voltage line DVL2 may be spaced apart from the end of the display panel 100 (or the substrate SUB).

On one side of the second driving voltage line DVL2 in the first direction DR1, multiple data lines DL may be arranged.

On one side of the first direction DR1 of the multiple data lines DL, the first driving voltage line DVL1 may be arranged. That is, the first driving voltage line DVL1 may be provided in multiple instances, and the second driving voltage line DVL2 may be arranged between the multiple first driving voltage lines DVL1. The end of the first driving voltage line DVL1 may be aligned with the end of the display panel 100 (or the substrate SUB).

On one side of the first driving voltage line DVL1 in the first direction DR1, the data line DL may be arranged, and on one side of the data line DL, the base voltage line EVL may be arranged.

On both sides of the first driving voltage line DVL1 and the second driving voltage line DVL2, data lines DL may be arranged, but the embodiments of this specification are not limited thereto.

The source film SF may include multiple source lines C_EVL, C_DL, C_DVL1, and C_DVL2, and each source line C_EVL, C_DL, C_DVL1, and C_DVL2 may overlap and be electrically connected to the lines EVL, DL, EVL1, and DVL2 of the display panel 100. An anisotropic conductive film ACF may further be disposed between the source lines C_EVL, C_DL, C_DVL1, and C_DVL2 and the lines EVL, DL, EVL1, and DVL2 of the display panel 100.

The end of the source film SF (or the first circuit substrate) may be spaced apart from the end of the display panel 100. Therefore, the ends of the source lines C_EVL, C_DL, C_DVL1, and C_DVL2 may be spaced apart from the ends of the display panel 100.

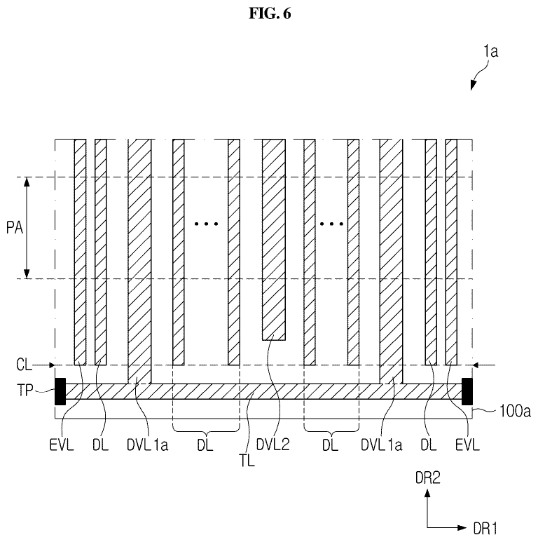

FIG. 6 is a plan view illustrating a process step in a method of manufacturing a display panel according to an embodiment.

Referring to FIGS. 4 to 6, the display panel 100a of the display apparatus 1a shown in FIG. 6 may be a panel before being cut along the cutting line CL. That is, the display panel 100 cut along the cutting line CL may be the final product. The first driving voltage line DVL1a of the display panel 100a may be extended further to the opposite side of the cutting line CL in the second direction DR2. The first driving voltage line DVL1a, extended to the opposite side of the cutting line CL in the second direction DR2, may be connected to the test line TL. The test line TL may extend in the first direction DR1 and may be connected to the test pads TP located at the ends of the first direction DR1 and the opposite side of the first direction DR1. A predetermined test driving voltage may be applied to the test pads TP, so the defects of the first driving voltage line DVL1a may be tested.

When the display panel 100a in FIG. 6 is cut, the end of the first driving voltage line DVL1a may be aligned with the end of the display panel 100 (or the substrate SUB), as shown in the display panel 100 of FIG. 4.

Hereinafter, descriptions of display apparatus according to other embodiments will be provided. In explaining the following embodiments, detailed descriptions of configurations that are the same as or similar to those described with reference to FIGS. 1 to 6 will be omitted to avoid redundancy.

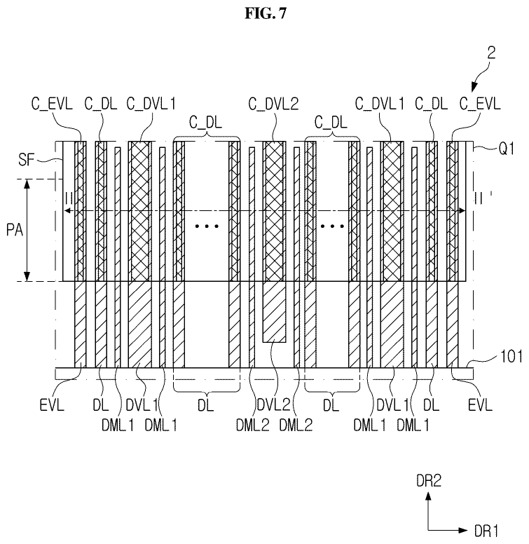

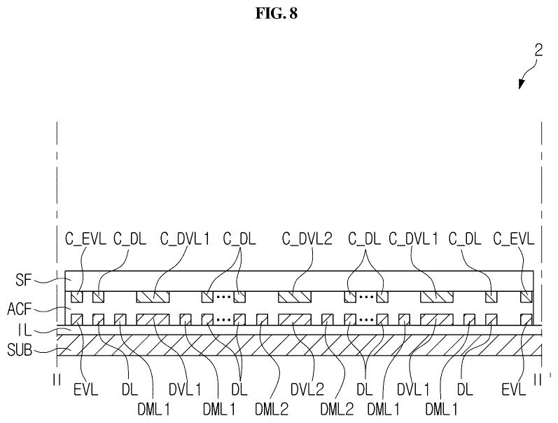

FIG. 7 is a plan view of a display apparatus according to another embodiment; FIG. 8 is a cross-sectional view taken along line II-II′ of FIG. 7 according to an embodiment.

Referring to FIGS. 7 and 8, the display panel 101 of the display apparatus 2 according to this embodiment may further include dummy lines DML1 and DML2. Each dummy line DML1 and DML2 may be positioned on opposite sides of the driving voltage lines DVL1 and DVL2. The first dummy line DML1 may be disposed between the first driving voltage line DVL1 and the data line DL, and the second dummy line DML2 may be disposed between the second driving voltage line DVL2 and the data line DL. The dummy lines DML1 and DML2 may not be electrically connected to the pixels PX, respectively. The dummy lines DML1 and DML2 may overlap with the source film SF. However, the source lines of the source film SF overlapping with the dummy lines DML1 and DML2 may not be disposed.

According to the display apparatus 2 of this embodiment, the display panel 101, by further including the dummy lines DML1 and DML2, may improve the short-circuiting between the driving voltage lines DVL1 and DVL2 and other adjacent lines (e.g., the data line DL).

The additional description that has already been made with reference to FIGS. 4 and 5 will be omitted.

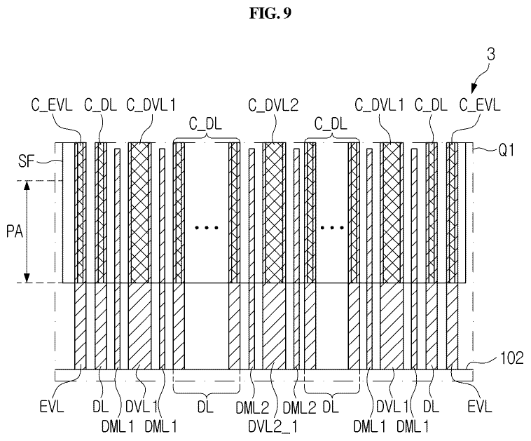

FIG. 9 is a plan view of a display apparatus according to another embodiment.

Referring to FIG. 9, the display panel 102 of the display apparatus 3 according to this embodiment differs from the display panel 101 of the display apparatus 2 in that it includes a second driving voltage line DVL2_1.

More specifically, the end of the second driving voltage line DVL2_1 may be aligned with the end of the display panel 100 (or the substrate SUB).

Meanwhile, in the case of the display apparatus 3 according to this embodiment, dummy lines DML1 and DML2 may also be included. Each dummy line DML1 and DML2 may be positioned on opposite sides of the driving voltage lines DVL1 and DVL2_1. The first dummy line DML1 may be disposed between the first driving voltage line DVL1 and the data line DL, and the second dummy line DML2 may be disposed between the second driving voltage line DVL2_1 and the data line DL. The dummy lines DML1 and DML2 may not be electrically connected to the pixels PX, respectively. The dummy lines DML1 and DML2 may overlap with the source film SF. However, the source lines of the source film SF overlapping with the dummy lines DML1 and DML2 may not be disposed.

According to the display apparatus 3 of this embodiment, the display panel 102, by further including the dummy lines DML1 and DML2, may improve the short-circuiting between the driving voltage lines DVL1 and DVL2_1 and other adjacent lines (e.g., the data line DL).

Further details are as described above with reference to FIG. 7 and will be omitted hereinafter.

The display apparatus according to various embodiments of this specification may be described as follows.

A display apparatus according to various embodiments of this specification includes a display panel including a pad area where a first driving voltage line and a second driving voltage line spaced apart from the first driving voltage line are arranged, and a first circuit substrate connected to the pad area, wherein an end of the first driving voltage line is aligned with an end of the display panel, and an end of the second driving voltage line is spaced apart from the end of the display panel.

In the display apparatus according to various embodiments of this specification, the pad area may further include a third driving voltage line spaced apart from the first driving voltage line with the second driving voltage line interposed therebetween, and an end of the third driving voltage line may be aligned with the end of the display panel.

In the display apparatus according to various embodiments of this specification, the pad area may further include a plurality of data lines arranged on both sides of the first driving voltage line or the second driving voltage line, and an end of each of the plurality of data lines may be aligned with the end of the display panel.

In the display apparatus according to various embodiments of this specification, the display panel may further include a display area where a pixel is arranged, and the first driving voltage line and the second driving voltage line may each be electrically connected to the pixel.

The display apparatus according to various embodiments of this specification may further include dummy lines arranged on both sides of the first driving voltage line.

In the display apparatus according to various embodiments of this specification, the dummy lines may not be electrically connected to the pixel.

In the display apparatus according to various embodiments of this specification, the dummy lines may overlap the first circuit substrate.

In the display apparatus according to various embodiments of this specification, the pad area may further include a plurality of data lines arranged on both sides of the first driving voltage line or the second driving voltage line, and the dummy lines may be arranged between the first driving voltage line and the plurality of data lines or between the second driving voltage line and the plurality of data lines.

In the display apparatus according to various embodiments of this specification, the pad area is spaced apart from the end of the display panel.

A display apparatus according to various embodiments of this specification includes a display panel including a pad area where a first driving voltage line and a second driving voltage line spaced apart from the first driving voltage line are arranged, and a first circuit substrate connected to the pad area, wherein an end of the first driving voltage line and an end of the second driving voltage line are each aligned with an end of the display panel, and dummy lines are further arranged on both sides of the first driving voltage line and on both sides of the second driving voltage line.

In the display apparatus according to various embodiments of this specification, the pad area may further include a plurality of data lines arranged on both sides of the first driving voltage line or the second driving voltage line, and an end of each of the plurality of data lines may be aligned with the end of the display panel.

In the display apparatus according to various embodiments of this specification, the dummy lines may be arranged between the first driving voltage line and the plurality of data lines or between the second driving voltage line and the plurality of data lines.

In the display apparatus according to various embodiments of this specification, the display panel may further include a display area where a pixel is arranged, and the first driving voltage line and the second driving voltage line may each be electrically connected to the pixel.

In the display apparatus according to various embodiments of this specification, the dummy lines may not be electrically connected to the pixel.

In the display apparatus according to various embodiments of this specification, the dummy lines may overlap the first circuit substrate.

In the display apparatus according to various embodiments of this specification, the pad area is spaced apart from the end of the display panel.

The embodiments of this specification are advantageous in providing a display apparatus capable of improving a short circuit (e.g., reducing an occurrence of the short circuit) between a driving voltage line and an adjacent line by additionally disposing dummy lines on both sides of the driving voltage line.

The embodiments of this specification are advantageous in terms of providing a display apparatus capable of enhancing longevity and reducing power consumption by improving a short circuit between the driving voltage line and an adjacent line.

The advantages achievable through this specification are not limited to the foregoing, and other advantages not explicitly described herein may be readily understood by those skilled in the art from the disclosure.

Although the embodiments have been described with reference to the attached drawings, it will be understood by those skilled in the art that the described technical configurations can be implemented in other specific forms without altering the technical essence or essential features. Therefore, it should be understood that the embodiments described above are exemplary and not limited in all respects. Moreover, the scope of the embodiments is determined by the claims that follow, rather than by the detailed description. Any modifications or variations derived from the meaning, scope, and equivalent concepts of the patent claims are to be considered as falling within the scope of the embodiments.

### DESCRIPTION OF REFERENCE NUMERALS

10: display apparatus

SPCB: source printed circuit board

CPCB: control printed circuit board

FFC: flexible flat cable

SF: source film

RVL: reference voltage line

DVL1, DVL2: driving voltage line

What is claimed is:

1. A display apparatus comprising:
a display panel comprising a pad area where a first driving voltage line and a second driving voltage line that is spaced apart from the first driving voltage line are arranged; and
a first circuit substrate connected to the pad area,
wherein an end of the first driving voltage line is aligned with an end of the display panel, and an end of the second driving voltage line is spaced apart from the end of the display panel.

2. The display apparatus of claim 1, wherein the pad area further comprises:
a third driving voltage line spaced apart from the first driving voltage line with the second driving voltage line interposed between the first driving voltage line and the second driving voltage line,
wherein an end of the third driving voltage line is aligned with the end of the display panel.

3. The display apparatus of claim 1, wherein the pad area further comprises:
a plurality of data lines on both sides of the first driving voltage line or the second driving voltage line,
wherein an end of each of the plurality of data lines is aligned with the end of the display panel.

4. The display apparatus of claim 1, wherein the display panel further comprises:
a display area where a pixel is arranged,
wherein the first driving voltage line and the second driving voltage line are each electrically connected to the pixel.

5. The display apparatus of claim 4, further comprising:
dummy lines on both sides of the first driving voltage line.

6. The display apparatus of claim 5, wherein the dummy lines are not electrically connected to the pixel.

7. The display apparatus of claim 5, wherein the dummy lines overlap the first circuit substrate.

8. The display apparatus of claim 5, wherein the pad area further comprises:
a plurality of data lines on both sides of the first driving voltage line or the second driving voltage line,
wherein the dummy lines are between the first driving voltage line and the plurality of data lines or between the second driving voltage line and the plurality of data lines.

9. The display apparatus of claim 1, wherein the pad area is spaced apart from the end of the display panel.

10. A display apparatus comprising:
a display panel comprising a pad area where a first driving voltage line and a second driving voltage line that is spaced apart from the first driving voltage line are arranged; and
a first circuit substrate connected to the pad area,
wherein an end of the first driving voltage line and an end of the second driving voltage line are each aligned with an end of the display panel, and dummy lines are further arranged on both sides of the first driving voltage line and on both sides of the second driving voltage line.

11. The display apparatus of claim 10, wherein the pad area further comprises:
a plurality of data lines on both sides of the first driving voltage line or the second driving voltage line,
wherein an end of each of the plurality of data lines is aligned with the end of the display panel.

12. The display apparatus of claim 11, wherein the dummy lines are between the first driving voltage line and the plurality of data lines or between the second driving voltage line and the plurality of data lines.

13. The display apparatus of claim 10, wherein the display panel further comprises:
a display area where a pixel is arranged,
wherein the first driving voltage line and the second driving voltage line are each electrically connected to the pixel.

14. The display apparatus of claim 13, wherein the dummy lines are not electrically connected to the pixel.

15. The display apparatus of claim 13, wherein the dummy lines overlap the first circuit substrate.

16. The display apparatus of claim 10, wherein the pad area is spaced apart from the end of the display panel.
